(19) United States
(12) Patent Application Publication
(10) Pub. No.: US 2016/0070033 A1
(43) Pub. Date: Mar. 10, 2016

(54) LIGHT-ABSORBING LAYER AND LAYER SYSTEM CONTAINING THE LAYER, METHOD FOR PRODUCING THE LAYER SYSTEM AND A SPUTTER TARGET SUITED THEREFOR

(71) Applicant: HERAEUS DEUTSCHLAND GMBH & CO. KG, Hanau (DE)

(72) Inventors: Martin SCHLOTT, Offenbach (DE); Albert KASTNER, Hanau (DE); Markus SCHULTHEIS, Flieden (DE); Jens WAGNER, Frankfurt (DE); Suk-Jae LEE, Gyeonggi-do (KR); Ben KAHLE, Alzenau (DE)

(21) Appl. No.: 14/783,849

(22) PCT Filed: Apr. 3, 2014
(86) PCT No.: PCT/EP2014/056668

§ 371 Date: Oct. 10, 2015

(30) Foreign Application Priority Data
Apr. 11, 2013 (DE) 10 2013 103 679.1

(51) Int. Cl. G02B 5/00; G02B 1/11; C23C 14/08; C23C 14/00; C23C 14/34; C23C 14/35

(52) U.S. Cl. CPC G02B 5/003; C23C 14/3414; C23C 14/35; C23C 14/08; C23C 14/0036; G02B 1/11

(57) ABSTRACT

A light-absorbing layer system includes an absorber layer having an oxidic matrix. The oxidic matrix is based on a base component made of zinc oxide, tin oxide and/or indium oxide, and on an added component which can replace the base component K1 up to a fraction of 75% by weight. The added component consists of niobium oxide, hafnium oxide, titanium oxide, tantalum oxide, vanadium oxide, yttrium oxide, zirconium oxide, aluminum oxide and/or mixtures thereof. A blackening component, made of molybdenum, tungsten and alloys and mixtures thereof, is distributed in the matrix and is present either as metal or as substoichiometric-oxidic compound of the metal, such that the layer material has a degree of reduction which is defined by an oxygen content of at most 65% of the stoichiometrically maximum oxygen content. The weight fraction of the blackening component is in the range between 20 and 50% by weight.

### TECHNICAL FIELD OF THE INVENTION

The invention refers to a light-absorbing layer which at a wavelength of 550 nm has an absorption index kappa of more than 0.7, and to a layer system containing such a light-absorbing layer.

Furthermore, the invention refers to a method for producing such a layer or such a layer system and to a sputter target for use in said method.

### PRIOR ART

Light-absorbing layer systems are e.g. produced by depositing successive layers by means of sputtering. Atoms or compounds are here ejected from a solid body, the sputter target, by bombardment with energy-rich ions (normally, noble gas ions) and pass into the gas phase. The atoms or molecules in the gas phase are ultimately deposited by condensation on a substrate positioned near the sputter target and form a layer there. In the case of “direct current sputtering” or “DC sputtering” a DC voltage is applied between the target, which is switched as a cathode, and an anode (often the system housing). Due to impact ionization of inert gas atoms a low-pressure phase is formed in the evacuated gas chamber, the positively charged constituents of said low-pressure plasma being accelerated by the applied DC voltage as a permanent particle stream towards the target, and particles are ejected from the target upon impact, the particles, in turn, moving towards the substrate and depositing there as a layer.

DC sputtering requires an electrically conductive target material because, otherwise, the target would become charged due to the permanent stream of electrically charged particles and the DC field would thereby be compensated. On the other hand, especially this sputter method is suited for delivering layers of a particularly high quality in an economic manner, so that its use is desired. This is also true for the technologically related MF sputtering in which two sputter targets are alternatingly switched in the kHz rhythm as cathode and anode.

Light-absorbing layer systems are used for various applications, for instance as solar absorber layers for solar-thermal applications or so-called “black matrix” layers in conjunction with liquid crystal displays.

EP 2 336 811 A1 discloses a layer sequence of an aluminum substrate, an intermediate layer of Al₂O₃ and a light-absorbing layer system. The layer system consists of a bottom layer of an Ti—Al mixed oxide or nitride or oxynitride with the general total formula: TiAlqOxNy), which may contain substoichiometric contents of oxygen and nitrogen and forms the absorber layer proper, and of a top layer of stoichiometric or of substoichiometric SiO₂.

In the solar absorber layers, the layer build-up typically comprises a cermet layer and an underlying metallic completion layer which serves as a selective reflector. In the cermet layer, metallic or other electrically conductive particles are embedded in a ceramic matrix, said particles typically having a diameter in the range of 5-30 nm. These layer stacks show a high degree of absorption in the solar spectral range (about 350-1500 nm), whereas their degree of absorption in the infrared spectral range is small. Electroplating techniques and PVD methods are in common use for the industrial manufacture of said layer systems. Examples of such layer stacks are Ni/NiO+Al and TiNx/TiO₂+Cu. An up-to-date overview is given by “Kennedy, C. E.;” Review of Mid- to High-Temperature Solar Selective Absorber Materials; NREL Technical Report (July 2002)”.

EP 2 116 631 A1 discloses a sputter target for producing a ZnO:Me2 layer or a TiO:Me2 layer. To accelerate and stabilize the sputter process, a sputter target is used having a matrix of a substoichiometric zinc or titanium oxide, in which a second metal M2 is embedded in addition, where Me2 stands for Al or niobium.

US 2007/0071985 A1 describes a great number of material compositions, especially for a sputter target. The compositions contain inter alia mixed oxides based on ZnO (also with indium oxide, tin oxide, aluminum oxide and gallium oxide) and molybdenum (IV)oxide (MoO2). The fraction of MoO₂ is said to be between 0.1 and 60 mole %. The densities of the target material vary between about 77% and 95% of the theoretical density. Molybdenum oxide in the form of MoO₂ is a stoichiometric oxide of the molybdenum, albeit not the oxide with the highest possible oxygen content MoO₃. It is added to the base oxide for improving the conductivity, but de facto, e.g. in the mixed oxide system ZnO:MoO2, it reaches good values only for small fractions of around 5-10 mole % MoO₂.

The target is produced by hot pressing in graphite molds under vacuum or by sintering in air.

The layer deposition by using the target is carried out by adding a small amount of oxygen in the deposition gas. The oxygen pressure is set to 10 mTorr, independently of the MoO₂ content of the target material, and is enough for compensating the oxygen loss normally observed during layer deposition.

The layers produced from the target are electrically conductive and show a transmission of at least 80%. They represent alternatives to otherwise common transparent and conductive layers, e.g. ITO layers.

CN 101158028 A describes a sputtering method for producing a layer called “ZMO transparent conductive film”. The target material consists of zinc in which Mo metal pieces are inserted (zinc-molybdenum metal inserted target). The molybdenum fraction is said to be 0.5 to 12.5% based on the zinc mass.

This target also serves the production of a transparent and conductive film. It is produced by reactive DC magnetron sputtering in a sputtering atmosphere containing argon and oxygen. The oxygen content is in the range of 4-10%.

### TECHNICAL OBJECT

In the production of the layer systems and their implementation in complex layer structures, dry or wet etching processes are required. Cermet layer systems, however, are normally difficult to etch because portions of a metallic phase require other etchants than does the oxidic matrix. Plasma etching has also turned out to be difficult. For instance, in combinations consisting of an oxide and a precious metal, it is the oxide that is predominantly etched, so that metal particles remain and may contaminate the sputter system and subsequent substrates.

Hydrofluoric acid which is harmful to health and can only be handled by taking great efforts is often needed for the wet-chemical etching of oxidic constituents. Moreover, the Cr-based “black matrix layers” which are above all used up to substrate generation 5 have the drawback that toxic Cr-VI compounds may form in wet-chemical etching.

For the above-discussed reasons layer structures are desired that show high absorption and low reflection in the visible spectral range and can be etched without the formation of toxic substances and without particle residues by using simple diluted acids. Metallic layers or sub-layers satisfy this prerequisite for the above-mentioned reasons.

On the other hand, because of quality considerations and for economic reasons the layers should preferably be producible by way of DC or MF sputtering, which presupposes an electrically conductive target material.

It is therefore the object of the present invention to indicate a light-absorbing layer and a layer system containing the layer that satisfies these demands.

Furthermore, it is the object of the present invention to provide a method for producing the layer system according to the invention and to provide a sputter target suited therefor.

### GENERAL DESCRIPTION OF THE INVENTION

### The Light-Absorbing Layer According to the Invention

As for the light-absorbing layer, this object starting from a layer of the aforementioned type is achieved according to the invention by a layer,
with an oxidic matrix, based on a base component K1, selected from the group consisting of zinc oxide, tin oxide and/or indium oxide, and on an added component K3 which replaces the base component K1 up to a fraction “y” between 0 and 75% by weight and which is selected from the group consisting of niobium oxide, hafnium oxide, titanium oxide, tantalum oxide, vanadium oxide, yttrium oxide, zirconium oxide, aluminum oxide and mixtures thereof,
wherein a blackening component K2 selected from the group consisting of molybdenum, tungsten and alloys and mixtures thereof is distributed in the matrix and is present either as metal or as substoichiometric-oxidic or substoichiometric-oxynitride compound of the metal in such a way that the layer material has a degree of reduction which is defined by an oxygen content of not more than 65% of the stoichiometrically maximum oxygen content, and wherein the fraction “x” of the blackening component K2-calculated from the weight of its elemental fraction based on the weight of the layer material—is in the range between 20 and 50 wt. %.

The light-absorbing layer should have an optically non-transparent, i.e. opaque, appearance for a viewer. Light absorption can be obtained by way of light-scattering or absorbing insertions of particles or deposits in an otherwise transparent layer matrix. When such layers are subjected to an etching operation in the further manufacturing process, particles or deposits may however show another etching behavior than the layer matrix and lead to an undesired formation of particles during etching of the layer system. This is particularly the case with metal particles that are difficult to etch, such as precious metal particles.

To avoid this, it is intended for the layer according to the invention that it consists of at least two components K1 and K2, with component K2 serving as the “blackening component” in the sense that it is present as a substoichiometric oxide (with oxygen deficits) or substoichiometric oxynitride (with oxygen or nitrogen deficits) or in metallic form and thereby has an electron configuration with free valences that produce the desired light absorption. This is not possible when the component K2 is present in an oxidation state determined by stoichiometry, e.g. as MoO₂ or as WO₂, even though this is not its respective, maximally possible degree of oxidation. As the chemical sum formula, the degree of reduction can be described as K2-O_{2-w} with: 0<w≦2).

All in all, no fully oxidic layer material is present according to the invention, but there is an oxidic or oxynitride layer material with substoichiometric oxygen content which by definition is defined by an oxygen content of not more than 65% of the theoretically maximally possible stoichiometric oxygen content. With respect to an optimum absorption the oxygen content is between 30% and 65%, particularly preferably between 40% and 60% of the theoretically maximally possible oxygen content.

The base component K1 is selected from the group: tin, indium and/or zinc. These components are normally present in the layer material in oxidic form. The blackening component K2 is present either as an easily etchable oxidic or oxynitride metal compound with substoichiometric oxygen content or in a metallic form; here, one or more of the following metals are suited for this, namely tungsten, molybdenum and mixtures and alloys of said substances. Alloys based on Mo and/or W which contain additions in the form of elements of the CAS groups IVb, Vb and Vlb (Ti, V, Cr, Zr, Nb, Hf, Ta) show optical properties that resemble those of the pure metals W and Mo or the mixtures of said pure metals.

Hence, the light-absorbing layer contains a substoichiometric oxide or a substoichiometric oxynitride which has unoccupied O- or N-valences. In the case of the substoichiometric oxynitride blackening component a small portion (preferably not more than 15%) of the oxygen sites is replaced by nitrogen.

Substances far away from their stoichiometric composition show a number of oxygen deficiency defects that manifest themselves under the spectroscope by way of a specific or blurred absorption in the visible wavelength range. Thus, solely due to the oxygen deficiency, the light-absorbing layer exhibits a strong absorption in the visible spectral range of 380-780 nm, but not up to 1,500 nm, as is achievable with metallic layers, and this without the need for crystalline particles or deposits.

For instance, substoichiometric materials of a ZnO maxtrix and inserted portions of substoichiometric molybdenum oxide show a distinct absorption in the visible wavelength range.

The degree of reduction of the absorber layer is defined by an oxygen content of not more than 65% of the stoichiometrically maximal oxygen content. It should be noted that the said degree of reduction refers to the absorber layer on the whole, but cannot exclusively be ascribed to the base component K1 or exclusively to the blackening component K2. Rather, it must be expected that all components of the layer are present more or less in a reduced state. The degree of reduction of the absorber layer is determined on the basis of the weight increase which follows when the layer material is pulverized in inert gas (particle size <10μ) and the powder is annealed in pure oxygen at 1000° C. for one hour. The degree of reduction R [%] is thus determined from the weight increase as follows: R[%]=100×weight increase/total weight of oxygen of the annealed sample.

The layer material consisting of the components K1 and K2 will also be called “base material” in the following. The quantitative amount of the blackening component K2 (e.g. the molybdenum amount) follows from the amount of substoichiometric oxide/oxynitride or metal within the matrix, wherein the amount is respectively determined from the weight that solely represents the elemental metal of the component K2, and the metal weight is related with the weight of the matrix. The metal weight amount of the blackening component K2 calculated in this way is in the range between 20 and 50 wt. %, preferably, however, it is at least 25 wt. %, and it is ideally in the range between 30 and 45 wt. %.

The base material consisting of K1 and K2 with the above-explained amounts yields a layer with the following properties:
It can be etched without particle formation by using diluted acids from the group HNO₃, HCl, and organic acids, such as oxalic acid, acetic acid, phosphoric acid and also by means of batches based on KOH+H₂O₂ or by adding fluoride-containing compounds such as NH₄HF₂. Fluoric acid is not needed.
At a wavelength of 550 nm, it has an absorption index kappa of more than 0.7.

For the absorption index, the following is applicable:

n*kappa=k,

with k=extinction coefficient which, in turn, is taken into account in the complex refractive index

N=n+i*k

and through which an attenuation amount by the imaginary part is taken into account in the refractive index of the layer.

The etch rate of the base material depends on the composition. Substoichiometric or metallic phases of the component K2 do not have the tendency to form structures that are difficult to etch. The etch rate is therefore primarily determined by the amount of the base component K1. Zinc oxide, tin oxide and indium oxide are however relatively easily etchable oxides with a comparatively high specific etch rate.

The etch rate of the base material can be reduced by a partial replacement of the oxygen by nitrogen, but this effect is small and at best suited for fine adjustment. The etch rate of the base material is substantially varied only within the limits set by the composition and particularly the amount of K1.

Particularly, the etch rate of the base material can hardly be slowed down below the specific etch rate given by K1 in combination with K2. In the case of particularly high demands made on the variability of the etch rate and particularly at a target etch rate that must be smaller than the specific etch rate of K1, the base material is however not very much suited.

According to the invention the etch behavior of the pure base material is therefore modified by replacing a part of the base component K1 by the added component K3. The added component K3, just like the base component K1, is present as a fully oxidized metal (=full oxide) or as a substoichiometric oxide (with oxygen deficiency) and is selected from the group consisting of niobium oxide, hafnium oxide, titanium oxide, tantalum oxide, vanadium oxide, yttrium oxide, zirconium oxide and/or aluminum oxide. The etch behavior of the layer material can be set through type, composition and quantitative amount of the added component K3 within limits that are broader than without the added component K3. Due to the addition the etch rate of the layer material is slowed down within wide limits and finely adjusted.

The oxidic added component K3 is etchable at a poorer rate, i.e. at a slower rate, than the oxidic base component K1. The added component K3, such as Nb₂O₅, replaces a part of the base component (such as ZnO), but not more than 75 wt. % thereof. Base component K1 and added component K3 taken together make up between 50 wt. % and 80 wt. % of the layer material. In this case the substantially oxidic matrix of the layer material is composed of the base component K1 and the added component K3; the blackening component K2 is distributed therein. The amount of the added component K3 is here calculated as the weight percentage of the added component K3 based on the total weight of the fully oxidic matrix.

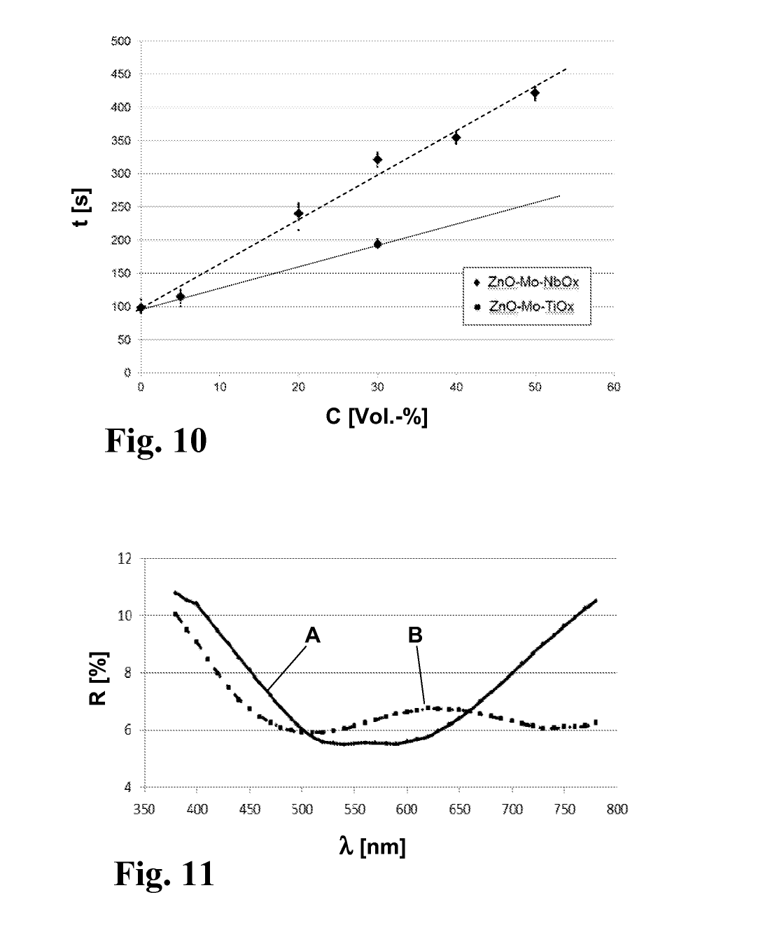

Base material and added component K3 are matched to each other such that the added component K3 slows down the etch rate of the base material. In this respect base materials with components K3, the composition of which on the whole can be subsumed by the above total formula, have not been described in the literature yet. Based on the understanding of the impact of the added component K3 on the etch rate of the base material, which may e.g. be linear as in FIG. 10, the above total formula permits a characterization of not fully oxidic layer materials without any complicated experimental examinations, without excluding the possibility that further suitable mixed oxide systems with compositions outside said total formula are found.

The etch behavior of the light-absorbing layer (absorber layer) or the etch behavior of a layer system containing the absorber layer can be adapted through the added component K3 to the etch rate of adjoining layers, for instance, to avoid a sub-etching of layers. Depending on the given specific etch rate of the layer material, the fraction y of the added component K3 is between 0 and <15 wt. % (for relatively high target etch rates), between 15 and <30 wt. % (for mean target etch rates), between 30 and <45 wt. % (for relatively low target etch rates) or between 45 and 60 wt. % (for very low target etch rates).

With respect to the optical properties of the layer material and particularly with respect to a kappa value that is as high as possible and a low reflection of the layer, it has turned out to be particularly advantageous when not more than one third of the base component is replaced by the added component K3.

The oxidic or predominantly oxidic added component K3 thereby replaces a part of the oxidic or predominantly oxidic base component K1, forming a mixed oxide structure therewith. Amounts of K2 are homogeneously distributed therein.

In connection with an etch behavior that is as homogeneous as possible, it is particularly advantageous when the layer material has a (radiographically) amorphous homogeneous structure in the sense that it is without crystalline structures that are detectable by way of X-ray diffractometer measurements.

This yields a homogeneous etch behavior, e.g. as in etching with fluoride ions or batches based on KOH+H₂O₂. Even under the transmission electron microscope the layers characterized in this way show no structures down to the resolution limit of 2 nm. Thermodynamically, however, the amorphous structure is unstable, whereby crystalline deposits may form due to annealing or heating up.

### The Layer System According to the Invention

As for the light-absorbing layer system, the above-mentioned object is achieved according to the invention by a first embodiment which comprises the light-absorbing layer according to the invention as an absorber layer facing away from a viewer, in conjunction with an antireflection layer facing the viewer, wherein the layer system in the wavelength range of 380-780 nm is characterized by a visual transmission Tv of less than 2% and a visual reflection Rv of less than 6%.

The layer system contains at least one light-absorbing layer, as has already been explained above, which is here also called “absorber layer”, and at least one antireflection layer. This shall be explained in more detail hereinafter.

The antireflection layer can be applied to a substrate of translucent material, e.g. to a glass plate, a plastic carrier, or a film. The antireflection layer is followed either directly or via one or more intermediate layers by the absorber layer of the invention, which may be provided with further functional layers.

The data on the visual transmission Tv and on the visual reflection Rv refer here to the whole layer system. The transmission normalized to eye sensitivity is here understood as the visual transmission Tv, which is calculated from the total transmission of the layer system. For the calculation of the visual transmission Tv the measurement values of a spectrometer are folded with the normalized eye-sensitivity factors and integrated or summed. These eye-sensitivity factors are laid down in DIN EN 410.

By analogy, visual reflection Rv stands for the reflection normalized to eye sensitivity, which is calculated from the total reflection of the layer system. As has already been explained for the visual transmission, the measurement values of the spectrometer are folded with the normalized eye-sensitivity factors and integrated or summed in an equivalent way also for the calculation of the visual reflection Rv, the eye-sensitivity factors being laid down in DIN EN 410. When the light-absorbing layer is applied to a transparent substrate, the reflection value on the non-coated surface of the substrate is deducted for calculating the visual reflection. The visual reflection Rv is less than 6%, preferably less than 3%.

The layer system on the whole is to have an optically non-transparent, i.e. opaque, appearance for a viewer. This requires a high absorption in the visible spectral range of 380-780 nm. At least in the rear sub-layer as seen by the viewer, i.e. the absorber layer, a small visual transmission Tv must therefore be guaranteed, so that a small visual transmission Tv in the said wavelength range of less than 2%, preferably less than 1%, and particularly preferably of less than 0.2%, is obtained for the layer system on the whole. For the same reason a small visual reflection Rv is desired, which is preferably less than 3%.

Preferably the same substances as for the absorber layer can be used in principle for the formation of the antireflection layer, but then with full stoichiometry or at best with a less pronounced oxygen deficiency. It has even turned out to be advantageous when the antireflection layer also shows a certain oxygen deficiency, but here the oxygen deficiency is smaller than in the absorber layer and the oxygen content is at least 95% of the stoichiometric oxygen content. It is not only the absorber layer, but also the antireflection layer that produces a certain absorption in this way, so that the total thickness of the layer system can be kept rather small for ensuring the necessary total absorption.

However, other dielectric layer systems which are used in the literature for antireflection coating, e.g. AlN, SnO₂, Si₃N₄, HfO₂, ZnO, TiO₂, HfO₂, Al₂O₃, silicon oxynitride or the mixtures thereof, are also suited.

The function of the antireflection layer, namely to keep the reflection of the incident light in the visible wavelength range as small as possible, is advantageously fulfilled in that it is applied to a substrate and has a refractive index n_{R}, where n_{S}<n_{R}<n_{A}, wherein n_{S} is the refractive index of the substrate, and n_{A} is the refractive index of the absorber layer. However, solutions are also feasible in the case of which the layer or the layer system is e.g. set against air.

Although it is technically easier to implement a double layer consisting of antireflection layer and absorber layer, a build-up of the layer system of several layers graded in their oxygen substoichiometry or also a gradient layer is possible, which seen in the viewing direction of the viewer could become continuously poorer in oxygen.

An essential function of the absorber layer is the generation of an absorption as high as possible of the optical radiation incident via the antireflection layer. Apart from the material of the absorber layer, parameters for fulfilling this function are its layer thickness and the degree of the oxygen deficiency.

With respect to the production costs, the total thickness of the layer system is as small as possible to observe a given maximum transmission. Essential parameters are here the oxygen deficiency and the thickness of the absorber layer. The necessary minimum thickness can be easily determined by way of tests. A layer build-up in which the light-absorbing layer has a layer thickness of less than 600 nm and is preferably in the range of 250 nm to 450 nm has turned out to be a suitable compromise between high absorption of the layer system on the one hand and coating costs on the other hand.

In the sense of a reflection which is as small as possible, in the direction opposite to the incident light, and of a good reflection adaptation to the absorber layer, the antireflection layer preferably has a thickness in the range of 45 nm to 60 nm.

With an increasing content of substoichiometric second component, e.g. with an increasing content of substoichiometric molybdenum oxide, i.e., with an increasing oxygen deficiency, the refractive index of the respective layer is increasing and thus the difficulty regarding an adequate antireflection coating. An optimum compromise between an optical absorption that is as high as possible, on the one hand, and a good antireflection coating, on the other hand, is achieved when the oxygen content of the absorber layer is between 30% and 60%, preferably between 40% and 60%, of the stoichiometric oxygen content of the fully oxidic layer. Hence, the absorber layer lacks between 30% and 65%, preferably between 40% and 60%, of the oxygen atoms that would be found in a fully stoichiometric dielectric layer.

The above-mentioned object is achieved according to the invention also by a further embodiment of the light-absorbing layer system which comprises the light-absorbing layer according to the invention as an absorber layer facing a viewer in conjunction with a metallic layer which faces away from the viewer and serves as a conductor path.

In this embodiment of the layer system, the light-absorbing layer (absorber layer) as has already been discussed above is applied directly or indirectly to a metallic layer and thereby conceals the layer for a viewer who is facing the absorber layer. The absorber layer is e.g. applied to electronic components and lines to conceal the same and to make them invisible for the viewer. The absorber layer itself can work against air or another optically denser, but transparent, medium, as is e.g. glass or plastic.

The metallic layer preferably contains one or more of the metals selected from the group: Al, Mo, Cu, Ti.

The metallic layer serves as a conductor path, resulting in high electrical conductivity. However, other properties, particularly etachability, play an important role as well. The metallic layer consists of the pure metal, of an alloy of the said metals among one another or of an alloy based on one of the said metals.

In this embodiment, less demands are made on the light absorption of the absorber layer than in the case of the above-explained layer system consisting of absorber layer and antireflection layer, for the metallic layer contributes to absorption and the total layer stack consisting of metallic layer and absorber layer must be highly absorbent only on the whole. As for the absorber layer, it is enough in this case and even advantageous when it is only partly absorbent and thus partly also has an antireflective effect.

Conversely, the layer thickness of the absorber layer may turn out to be small, which reduces the manufacturing costs. In this respect it has turned out to be useful when in this embodiment of the light-absorbing layer system the combination of metallic layer and absorber layer in the wavelength range of 380-780 nm shows a visual transmission Tv of less than 8%, preferably less than 4%, and a visual reflection Rv of less than 15%, and a total thickness of less than 90 nm, preferably less than 60 nm.

On the other hand, it may even be desired when the absorber layer contributes to electrical conduction. In this respect the layer system is characterized by a layer resistance of less than 100 ohm/square.

Depending on the type of the metal of the metallic layer, different dimensions have turned out to be advantageous.

In one embodiment of the layer system in which the metallic layer consists of aluminum or an aluminum base alloy, the metallic layer preferably has a thickness in the range of 17-21 nm, the thickness of the absorber layer being in the range of 30-50 nm and preferably not more than 40 nm.

In another embodiment of the light-absorbing layer system in which the metallic layer consists of molybdenum or of a molybdenum base alloy, the metallic layer preferably has a thickness in the range of 15-50 nm, particularly preferably in the range of 25-35 nm, wherein the thickness of the absorber layer is in the range of 35 nm to 50 nm and is preferably not more than 40 nm.

In a further advantageous embodiment of the light-absorbing layer system, the metallic layer consists of copper or a copper base alloy and has a thickness in the range of 40 nm to 50 nm, wherein the thickness of the absorber layer is in the range of 28 nm to 50 nm and preferably not more than 40 nm.

### The Sputter Target According to the Invention

The above-mentioned object is achieved with respect to the sputter target particularly for producing a light-absorbing layer or a light-absorbing layer system according to the invention in that it consists of a target material
with an oxidic matrix, based on a base component K1, selected from the group consisting of zinc oxide, tin oxide and/or indium oxide, and on an added component K3 which replaces the base component K1 at a fraction “y” between 0 and 75 wt. % and which is selected from the group consisting of niobium oxide, hafnium oxide, titanium oxide, tantalum oxide, vanadium oxide, yttrium oxide, zirconium oxide, aluminum oxide and mixtures thereof,
wherein a blackening component K1 is distributed in the matrix, the blackening component being selected from the group consisting of molybdenum, tungsten and alloys and mixtures thereof, wherein the blacking component K2 is present either as a metal and/or as a substoichiometric-oxidic or substoichiometric-oxynitride compound of the metal, and has a degree of reduction which is defined by an oxygen content of not more than 65% of the stoichiometrically maximal oxygen content, and wherein the fraction “x” of the blackening component K2—calculated from the weight of its metal fraction based on the weight of the target material—is in the range between 20 and 50 wt. %.

The target base material of the sputter target according to the invention differs from the base material of the absorber layer. As a rule, it contains crystalline phases in metallic or oxidic form and consists of a completely or predominantly oxidic phase formed by one or more oxides of the base component K1, and of a strongly substoichiometric or metallic phase of the blackening component K2, such as e.g. of substoichiometric molybdenum oxide and/or molybdenum metal.

The amount in the blackening component K2 in oxidic and/or metallic form is calculated from the weight, which solely relates to the elemental metal of the compound K2, with the metallic weight being related with the weight of the target material on the whole. The weight percentage of the blackening component K2 calculated in this way is in the range between 20 and 50 wt. %, but it is preferably at least 25 wt. %, and it is ideally in the range between 30 and 45 wt. %.

The composition of the target base material substantially corresponds to that of the base material of the light-absorbing layer according to the present invention, particularly as far as the oxygen content and/or nitrogen content is concerned. This has the advantage that the light-absorbing layer can be produced using the sputter target without or only with a small addition of reactive gas. In contrast to the sputtering of a fully metallic target, a higher process stability and an easier process control are thereby also possible in MF or DC sputtering, for otherwise particularly in the case of large-area coatings reactive sputtering might soon encounter technological feasibility limits.

The boundary conditions regarding property and production of the light-absorbing layer can be satisfied if it is produced by MF or DC sputtering of such a sputter target. This has an oxygen deficiency which is set either by a reduced oxide or oxynitride phase of substoichiometric and thus electrically conductive metal oxide of the blackening component K2 or by a metallic admixture of the blackening component to the oxide of the base component K1. The last-mentioned embodiment should normally be preferred as strongly substoichiometric oxides are difficult to represent.

Alloys based on the blackening component Mo and/or W which contain additions in the form of elements of the CAS groups IVb, Vb and Vlb (Ti, V, Cr, Zr, Nb, Hf, Ta) show optical properties which resemble those of the pure metals W and Mo or the mixtures thereof.

ZnO+MoO_{2-w} (0<w≦2) should be mentioned as examples of the base material, wherein MoO_{2-w} represents a substoichiometric oxide or oxynitride of molybdenum or metallic molybdenum (for w=2). The target base material consists of a first phase, based on zinc oxide in which a second phase of molybdenum oxide with substoichiometric content of oxygen, or of molybdenum oxide with substoichiometric content of oxygen and metallic molybdenum or of exclusively metallic molybdenum is embedded.

The etching behavior of a sputter layer produced from the base target material is primarily determined by the fraction of the base component K1 and the blackening component K2, i.e. components that can be etched relatively easily. The etch rate of the base material can therefore be varied in a first approximation only within the limits set by the composition and the fraction of first component K1, and often turns out to be too fast.

Moreover, the etch rate of the base target material can be reduced by partial replacement of the oxygen by nitrogen. The reduction of the etch rate which can be achieved thereby is however limited, so that the target base material does not meet particularly high demands made on the variability of the etch rate.

Optionally, the base material of the sputter target contains an added component K3 so as to be able to modify the etch behavior of the layer produced therefrom to a significant extent. A part of the base component K1 is here replaced by an additional added component K3. The added component K3 is present as an oxide of a metallic element and is selected from the group consisting of niobium oxide, hafnium oxide, titanium oxide, tantalum oxide, vanadium oxide and/or aluminum oxide. Due to the added component K3 the etch rate of the target material can be set within limits that are wider than without the added component K3. Hence, the etching behavior of the target material is varied and finely adjusted through the type, composition and quantitative share of the added component K3.

The added component K3 comprises an oxide or several oxides from the above-defined group that is etchable under greater difficulties, i.e. at a slower rate, than the oxidic base component K1. For the adjustment of the etch rate of the base material the added component K3, such as Nb₂O₅, replaces a part of the base component (such as ZnO), but not more than 75 wt. % thereof. The amount of the added component K3 is here calculated as the weight percentage of the oxides to be ascribed to the added component in the total weight of the target material.

Depending on the given specific etch rate of the layer material to be produced, the percentage of the added component K3 is between 0 and <15 wt. %, between 15 and <30 wt. %, between 30 and <45 wt. % or between 45 and 60 wt. %. With respect to the optical properties of the layer material to be produced and particularly with respect to a kappa value that is as high as possible, it has however turned out to be particularly advantageous when not more than one third of the base component is replaced by the added component K3.

Preferably, the component K2 is present in metallic form.

The metallic form of the component can be provided in a technically easier and better reproducible manner than a strongly substoichiometric form. The ductile phase of the target material effects a higher density, reduces mechanical stresses and contributes to a greater strength. It has turned out to be useful when the metallic blackening component amounts to at least 50%, preferably at least 70% for adjusting the substoichiometry of the sputter target.

By comparison, the added component K3 is advantageously present as an oxide.

The metal fractions or substoichiometric oxides of the sputter target form electrically conductive phases, so that it can be processed by means of DC or MF sputtering. For this purpose its specific electrical resistance is less than 10 ohm*cm and particularly preferably less than 1 ohm*cm.

In the sputter target according to the invention the oxygen deficiency of the light-absorbing layer or the layer system according to the invention is substantially already given in that the oxygen deficiency of the sputter target corresponds approximately to that of the layer to be respectively sputtered or slightly exceeds said deficiency. A fine adjustment of the layer stoichiometry can be achieved through small additions of reactive gases (particularly of oxygen), so that the said technological difficulties are avoided during sputtering of metal targets under a highly reactive atmosphere. Apart from oxygen, the addition of other reactive gases such as nitrogen is also suited.

The oxygen deficiency of the sputter target is preferably defined by a degree of reduction at which the oxygen content is between 30 and 65%, preferably between 40 and 60%, of the stoichiometric oxygen content.

During sputtering a predetermined oxygen deficit is set in the deposited layer. The percentage of blackening component K2 in the target material is set such that it represents 50% or more of this deficit.

It has turned out to be advantageous when the degree of reduction remains as constant as possible over the thickness of the sputter target. Therefore, the substoichiometric sputter target preferably has a degree of reduction which measured at at least 5 points over the thickness of the sputter target varies by not more than +−5% (relative) around a mean value.

In the simplest case the degree of reduction is determined in that at least five samples with a weight of 1 g are taken from different thickness portions of the target layer and the increase in weight is determined on these samples, which increase follows when the target material is pulverized under inert gas (particle size <10 μm) and the powder is annealed in pure oxygen at 1000° C. for 1 hour. The degree of reduction R [%] is thus determined from the weight increase as follows:

R[%]=100×weight increase/total weight in oxygen of the annealed sample.

In addition, the degree of reduction can be verified in that at least five samples with a weight of 1 g are taken from different thickness portions of the target layer and the oxygen content is determined on these samples through the conversion to CO and a carrier gas extraction. The homogeneous degree of reduction contributes to a high process stability in the sputtering process and to the generation of sputter layers with reproducible properties.

In this respect it has also turned out to be useful when the possible metallic blackening component as an admixture defines a metal content which measured at at least 5 points over the thickness of the sputter target varies by not more than +−5% (relative) around a mean value.

With respect to a uniform sputtering of the sputter target the target material preferably has a density of more than 95% of the theoretical density and a content of impurities of less than 500 wt. ppm.

All elements that are not intentionally added as dopants or additions to the target material are here regarded as impurities.

The degree of reduction of the target material is preferably defined by an oxygen content between 30 and 65%, preferably between 40 and 50%, of the theoretically maximally possible oxygen content.

It is determined through annealing of the pulverized target material at 1000° C., as has already been explained further above for the absorber layer. The degree of reduction R [%] is determined from the weight increase as follows:

R[%]=100×weight increase/total weight of oxygen of the annealed sample.

### The Production Method According to the Invention for the Light-Absorbing Layer

The above-mentioned object is achieved with respect to the method for producing the light-absorbing layer or the light-absorbing layer system by DC or MF sputtering of a sputter target according to the invention in that sputtering is carried out in a sputtering atmosphere that contains a noble gas and a reactive gas in the form of oxygen and/or nitrogen, the reactive gas content in the sputter atmosphere being set to not more than 10 vol. %, preferably to not more than 4 vol. %.

The method according to the invention is characterized, on the one hand, by the interaction of a hardly reactive sputter atmosphere and, on the other hand, by use of a sputter target that contains an oxide of the base component K1 and a substoichiometric blackening component K2 (such as e.g. molybdenum oxide or molybdenum metal). The deposited (absorber) layer does not substantially differ in its chemical composition from that of the target material used. This permits a stable conduction of the sputter process and the reproducible adjustment of the properties of the deposited layer.

This is also supported by a particularly preferred modification of this procedure in which, each time based on ideal full stoichiometry, the percentage of oxygen in the material of the sputter target is as great as or only slightly smaller than the percentage of oxygen of the light-absorbing layer, wherein the oxygen percentage in the material of the sputter target represents, however, at least 50%, preferably at least 70%, of the oxygen percentage in the absorber layer.

The target material can thereby be transferred in unchanged form or only with a minor oxidation into the substoichiometric oxide of the light-absorbing layer. Attention must here be paid that a certain oxygen loss is normally observed in the sputter process, which loss may also make a small contribution to the adjustment of the desired substoichiometry of the light-absorbing layer.

In a particularly simple procedure a sputter target with a nominally identical composition is used for the deposition of an antireflection layer and for the deposition of an absorber layer, wherein the sputter atmosphere in the deposition of the antireflection layer has a higher reactive-gas content than in the deposition of the absorber layer, such that in the antireflection layer an oxygen deficit is obtained, which—based on the weight of oxygen of a stoichiometric layer—is less than 5%.

The increased reactive-gas addition in the deposition of the antireflection layer must here be chosen such that the antireflection layer becomes adequately dielectric.

### EMBODIMENT

The invention will now be explained in more detail with reference to a patent drawing and an embodiment. In detail,

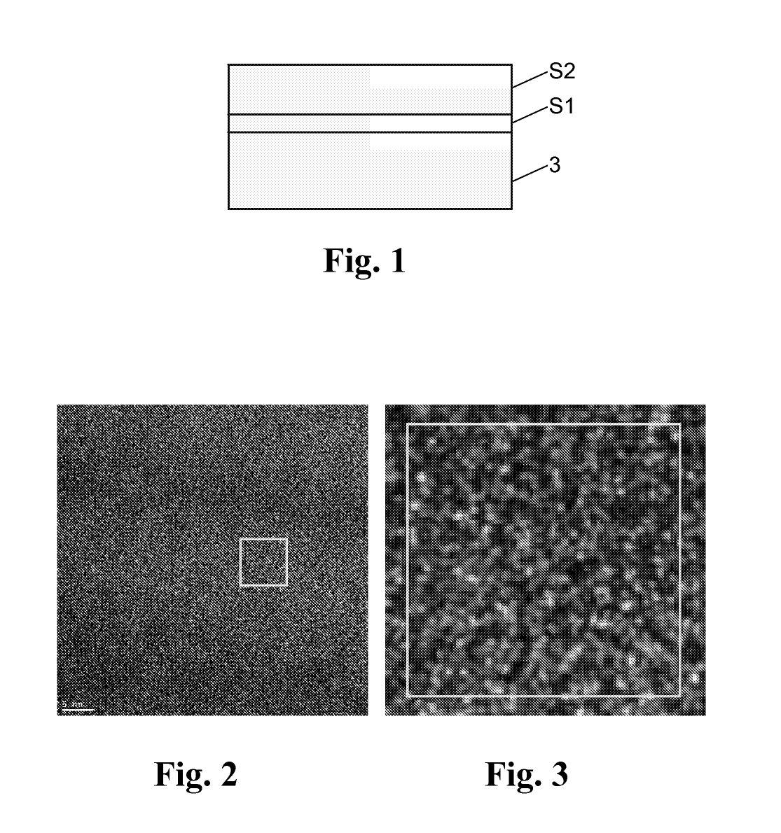

FIG. 1 is a schematic representation of the layer system according to the invention in a cross section,

FIG. 2 is an electron micrograph of a section of the layer system of FIG. 1,

FIG. 3 is a TEM image of the section of FIG. 2 with maximum magnification,

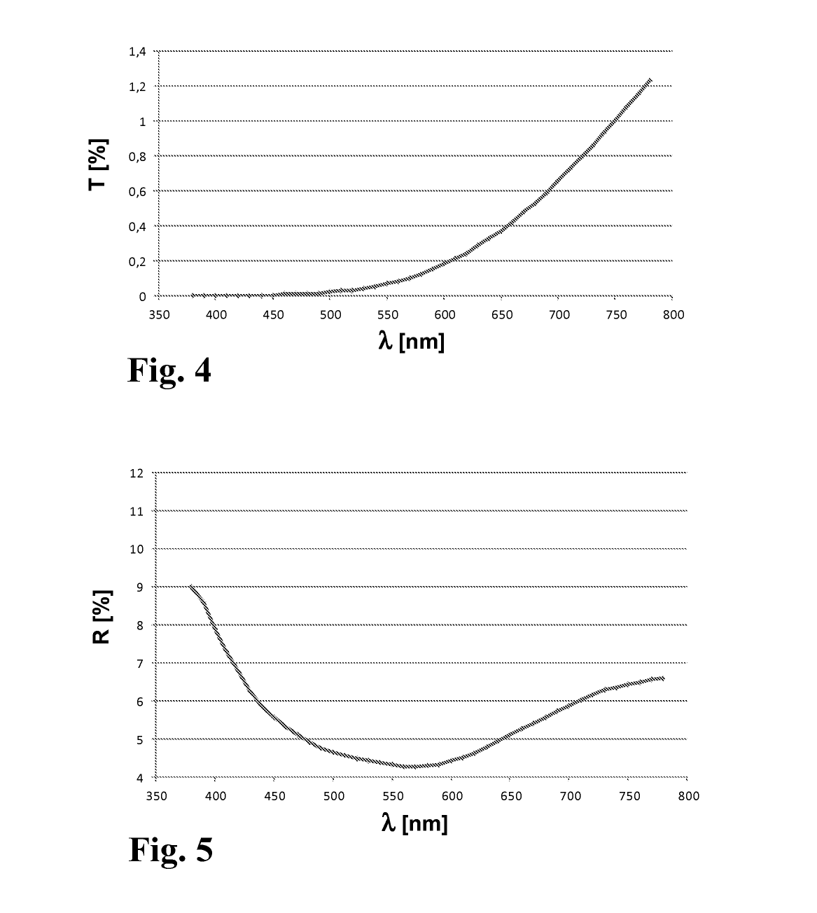

FIG. 4 shows the spectral curve of the transmission of a first embodiment of the layer system according to the invention,

FIG. 5 shows the spectral curve of the reflection of the same embodiment,

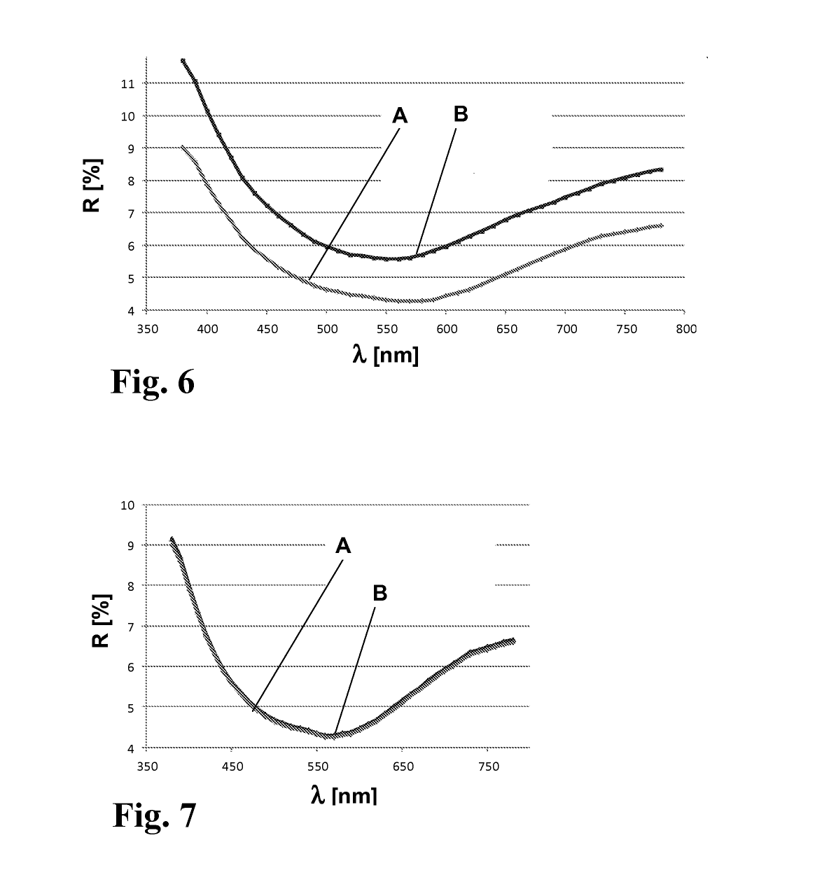

FIG. 6 shows a comparison of the reflection curves of first embodiment and a second embodiment of the layer system,

FIG. 7 shows a comparison of the reflection curves of first embodiment and a third embodiment of the layer system according to the invention,

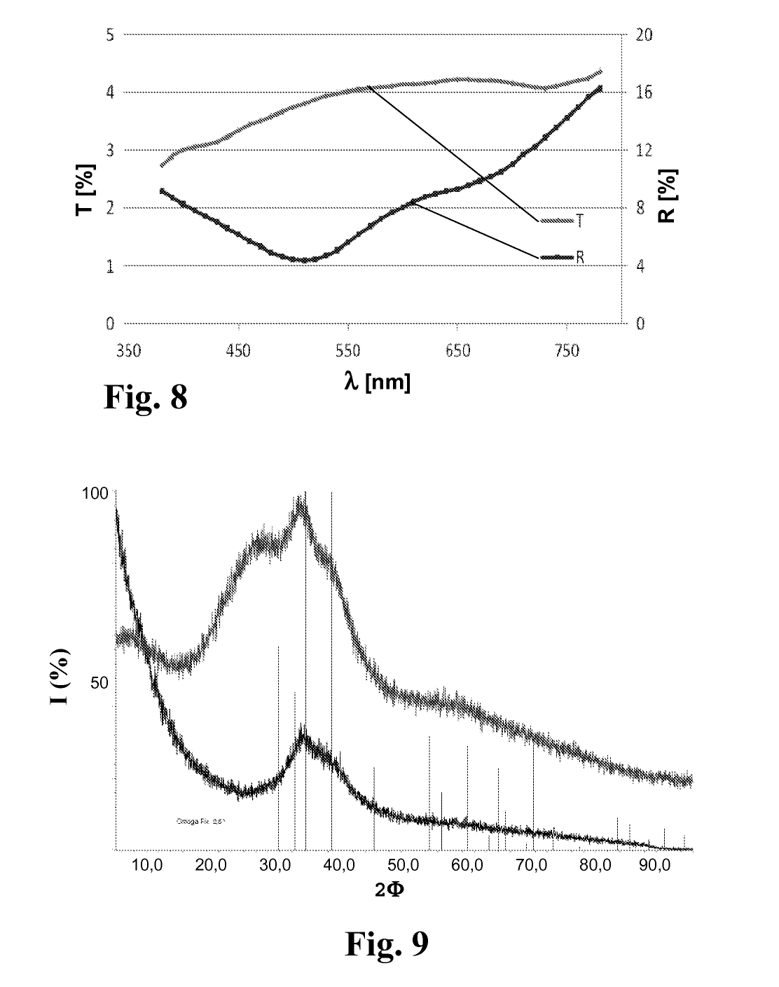

FIG. 8 shows transmission and reflection curves of a further embodiment of the layer system according to the invention,

FIG. 9 shows an X-ray diffraction diagram of the layer according to the invention,

FIG. 10 is a diagram on the etch behavior of various target materials according to the invention,

FIG. 11 shows reflection curves for two layer systems on the basis of ZnO+Mo+Nb₂O₅,

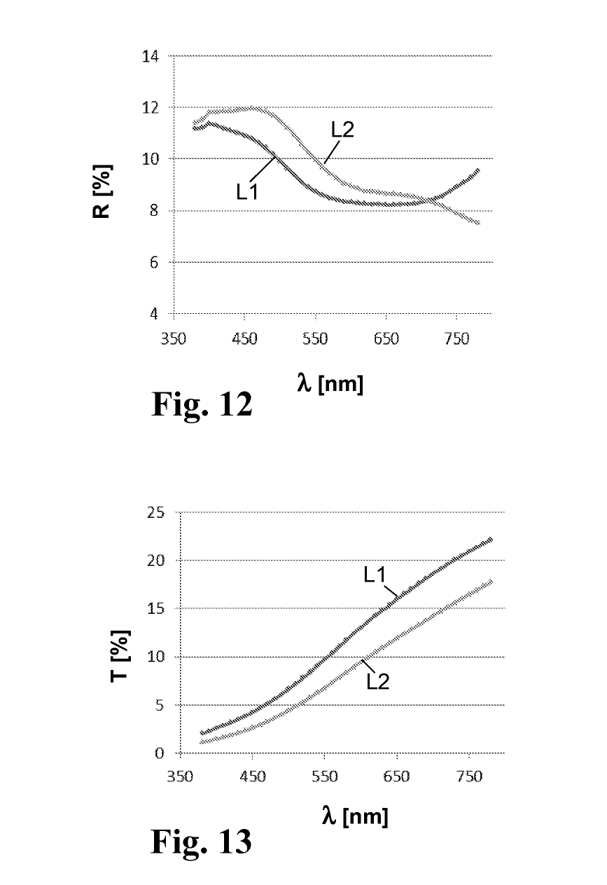

FIG. 12 shows reflection curves of a single-layered absorber layer according to the invention, and

FIG. 13 shows transmission curves of a single-layered absorber layer according to the invention.

### EXAMPLE 1

### Layer Systems of Antireflection and Absorber Layer

FIG. 1 schematically shows a layer system 1 according to the invention consisting of two layers S1, S2. The first layer is an antireflection layer S1 applied to a transparent glass plate 3, and the second layer is an absorber layer S2 produced on the antireflection layer S1. The layer thickness of the antireflection layer S1 is about 49 nm and the layer thickness of the absorber layer S2 is about 424 nm (corresponding to Sample 1 of Table 1).

Each of the layers S1 and S2 consists of a zinc and molybdenum oxide layer with different oxygen deficiency. The oxygen content of the antireflection layer S1 is 95% of the stoichiometric oxygen content. The oxygen content of the absorber layer S2 is smaller and is in the range of 35 to 70% of the stoichiometric oxygen layer. For a viewer with a viewing direction from the glass plate 3 the layer system is almost opaque and almost black at the same time.

The oxygen content of the layers is determined by means of EPMA (Electron Probe Microscope Analysis) measurements. An electron beam is here directed onto the sample and the X-ray radiation produced thereby is analyzed. It can be calibrated against standards, so that the relative measurement error is about 3-4%, and the oxygen content of the substoichiometric layer can be determined to be about +−3-4 atomic %. To avoid measurement errors caused by the substrate, layers with >1 μm thickness should best be produced.

FIG. 2 shows an electron micrograph of a section of this material. In the TEM image of FIG. 3 with maximum resolution, metal deposits can also not be detected.

This result is confirmed by the X-ray diffraction diagram of the layer materials in FIG. 9, which shows the scatter intensity I over the diffraction angle 2Φ. Concrete diffraction lines cannot be seen; both layers of the layer system are X-ray amorphous.

Table 1 shows the respective metal contents of the sputter target used for production and layer thickness d of the layers S1 and S2 for the layer system based on substoichiometric zinc and molybdenum oxide. The data on the molybdenum content refer to the weight percentage of metallic molybdenum in the sputter target, based on the matrix of zinc oxide. Moreover, measurement values for the transmission T_{V}, the reflection Rᵥ (less 4% for the reflection on the front side of the uncoated glass substrate), the absorption coefficient kappa of the produced layer structure and the electrical layer resistance RT are indicated.

TABLE 1
(examples ZnO + Mo)

| | | S1 | S1 | S2 | S2 | | | kappa | |
|---|---|---|---|---|---|---|---|---|---|
| | | Mo | d | Mo | d | Rv | Tv | @ | R [symbol] |
| No. | Matrix | [wt. %] | [nm] | [wt. %] | [nm] | [%] | [%] | 550 n | [ohm] |
| 1 | ZnO | 31.4 | 49 | 31.4 | 424 | 0.8 | 0.1 | 0.737 | 555 |
| 2 | ZnO | 37.9 | 50 | 31.4 | 423 | 0.9 | 0.1 | 0.737 | 550 |
| 3 | ZnO | 37.9 | 55 | 37.9 | 307 | 2.3 | 0.1 | 0.977 | 725 |
| 4 | ZnO | 31.4 | 55 | 37.9 | 308 | 2.2 | 0.1 | 0.977 | 720 |
| 5 | ZnO | 31.4 | 48 | 31.4 | 252 | 1.3 | 1.4 | 0.737 | 924 |
| 6 | ZnO | 37.9 | 49 | 31.4 | 252 | 1.4 | 1.4 | 0.737 | 920 |
| 7 | ZnO | 37.9 | 56 | 37.9 | 322 | 2.2 | 0.08 | 0.977 | 650 |

Table 1 shows that in the antireflection layer S1 the Mo content has no significant influence on the reflection. By contrast, in the absorber layer the reflection is decreasing with a decreasing Mo content, whereas the transmission is increasing with a decreasing Mo content.

A method for producing the layer system according to the invention shall now be explained in more detail with reference to an example:

### Target Production—Procedure 1

A powder mixture of 68.6 wt. % ZnO (mean grain size <5 μm) and 31.4 wt. % Mo with a mean grain size of 25 μm is intensively mixed in a tumble mixer for 1 h, resulting in a fine and monodisperse distribution of the Mo particles in ZnO. Subsequently, this mixture is filled into a graphite mold with a diameter of 75 mm and a height of 15 mm. The round blank is densified by hot pressing at 1150° C. and 30 MPa to 85% of the theoretical density. The structure obtained thereby consists of ZnO matrix into which Mo particles with a mean grain size of 25 μm are embedded.

### Target Production—Procedure 2

A second sputter target with 62.1 wt. % ZnO and 37.9 wt. % Mo is produced, a Mo powder with <10 μm grain size being selected for producing a particularly uniform Mo distribution. After mixing the powder is filled into a graphite-lined can of steel, it is degassed at 400° C. for 2 h and hot-isostatically pressed after welding of the can at 1050° and at 150 MPA. The body obtained has a density of 99% of the theoretical density and is cut with a diamond saw into discs and processed by grinding into 75 mm target discs. The sputter targets produced thereby typically have a specific electrical resistance of less than 1 ohm*cm.

### Target Production—Procedure 3

Thermal spraying is also suited for the production of the sputter target, e.g. plasma spraying of tube targets using a mixture of molybdenum powder (metallic) and ZnO agglomerates with agglomerate sizes in the range of e.g. 10-70 μm. The range limits are each obtained as d₁₀ value and d₉₀ value, respectively, of said particle size distribution. The molybdenum powder is here present in a finely divided form with grain sizes of less than 20 μm, preferably with a particle size distribution that is characterized by a d₁₀ value of 2 μm and a d₉₀ value of 10 μm.

### Layer System Production by Means of Target According to Procedure 1

Using the sputter target according to procedure 1, the two-layered structure S1, S2 is applied to a glass substrate 3 of the size 2 cm×2 cm and a thickness of 1.0 mm by means of DC sputtering. A first layer S1 with a thickness of 49 nm is first applied to the glass substrate 3 and a second layer S2 with a thickness of 424 nm is subsequently applied thereonto.

The sputter parameters are as follows:
Residual gas pressure: 2*10⁻⁶ mbar
Process pressure: 3*10⁻³ mbar at 200 sccm argon
Specific
cathode power: 5 W/cm²
Layer S1: target: 68.6 wt. % ZnO+31.4 wt. % Mo; d=49 nm, additional oxygen stream: 50 sccm
Layer S2: target: 68.6 wt. % ZnO+31.4 wt. % Mo; d=424 nm, additional oxygen stream: 10 sccm.

In this example both layers S1, S2 are thus sputtered from one and the same target which contains ZnO and an amount of metallic molybdenum of 31.4 wt. %. The different oxygen stoichiometries are here only set by the oxygen stream during sputtering. During sputtering of the absorber layer S2 the sputter atmosphere was supplied with less oxygen than during sputtering of the antireflection layer S1.

An oxygen stream of 50 sccm (these are 20 vol. % oxygen in the sputter atmosphere in the embodiment) corresponds to an oxygen stream that is still technologically feasible without any problems.

Under these conditions the layer S1 is almost fully oxidic, whereas S2 has about the oxygen deficiency of the target material. To obtain fully dielectric layers from a fully oxidic target, a system-specific oxygen stream is needed under the given conditions to compensate for the loss of oxygen by the pumps. The necessary oxygen flow for fully dielectric layers follows in a first approximation from the metal content (oxygen deficiency) of the used target for this layer. For different sputter systems and target mixtures the corresponding value must first be determined in a few tests, and the oxygen flow must be adapted accordingly. The layer structure produced thereby is inter alia distinguished by the following properties:

layer resistance: R [symbol] =555 kΩ/square
visual reflection (after deduction of about 4% reflection by measurement of the uncoated substrate side): 0.8%
   visual transmission: 0.1%
the absorption coefficient kappa of the produced layer structure 1 is 0.737 for the wavelength 550 nm.

Other advantageous embodiments of the layer system and additional layer properties are indicated in Table 1.

Table 2 summarizes the deposition parameters and the associated measurement results on the deposited layers for Samples 1 to 7.

TABLE 2
(examples ZnO + Mo/deposition conditions)

| | | S1 | S1 | O2 | S2 | S2 | O2 flow |
|---|---|---|---|---|---|---|---|
| | | Mo | d | flow S1 | Mo | d | S2 |
| No. | matrix | [wt. %] | [nm] | [sccm] | [wt. %] | [nm] | [sccm] |
| 1 | ZnO | 31.4 | 49 | 40 | 31.4 | 424 | 10 |
| 2 | ZnO | 37.9 | 50 | 50 | 31.4 | 423 | 10 |
| 3 | ZnO | 37.9 | 55 | 50 | 37.9 | 307 | 0 |
| 4 | ZnO | 31.4 | 55 | 40 | 37.9 | 308 | 0 |
| 5 | ZnO | 31.4 | 48 | 40 | 31.4 | 252 | 0 |
| 6 | ZnO | 37.9 | 49 | 50 | 31.4 | 252 | 0 |
| 7 | ZnO | 37.9 | 56 | 50 | 37.9 | 322 | 0 |

In FIG. 4 the transmission T (in %) is plotted against the measurement wavelength λ (in nm) for the layer system according to FIG. 1 and Sample 1 of Table 1. Hence, the transmission T over the wavelength range of 380 nm to 780 nm is increasing with the wavelength, but remains below 1.4%.

FIG. 5 shows the curve of the reflection R (in %) over the wavelength range λ (in nm) of 380 nm to 780 nm for this layer system. The reflection shows a minimum at about 555 nm with a reflection value of slightly more than 4%, but it remains below 9% over the whole wavelength range, so that after deduction of a reflection value of 4%, which is due to reflection on the not antireflection-coated glass plate front side, one obtains a reflection below 5% that can really be ascribed to the layer system.

During storage of the layer structure at 18-24° C. and 50-60% relative air humidity for up to 5 days the optical properties changed only insignificantly. The change of Rv and Tv was below one percentage point each time.

The layer system can be etched without formation of objectionable metal particles by means of diluted, fluorine-free acids and can also be structured in solutions of KOH+H₂O₂ or under addition of NH₄HF₂. Likewise in other etching methods, such as plasma etching, no objectionable particle formation is observed. Tests regarding the etch behavior of the base materials according to Table 3 and of modifications of said materials shall be discussed further below in more detail.

FIG. 6 shows a comparison of the spectral reflection curves of Sample No. 1 (curve A) and of Sample No. 4 (curve B) of Table 1. The reflection R (in %) is plotted over the wavelength range λ (in nm). In the case of Sample No. 4 the absorber layer S2 has a comparatively higher molybdenum oxide content. It has been found that the higher molybdenum oxide content in the absorber layer S2 leads to a higher reflection of the layer system on the whole.

Therefore, for a low reflection of the layer system the molybdenum content of the layer system should be as low as possible (in the embodiment 31.4 wt. % (the mass of molybdenum metal to be derived from the molybdenum oxide, based on the total mass of the absorber layer)) if both the absorber layer S2 and the antireflection layer S1 are to be produced from the same target material.

On the other hand, the comparison of the reflection curves of Samples 1 and 2 (of Table 1) of FIG. 7, in which the reflection R (in %) is also plotted over the wavelength range λ (in nm), shows that a higher molybdenum oxide content in the antireflection layer S1 (like in Sample 2) has no impact on the reflection of the layer system. Here, curves A and B extend laid one upon the other over the whole wavelength range.

### Example 2

### Layer Systems of Conductor Path and Absorber Layer

A further layer system according to the invention refers to “black conductor paths”. These consist of a thin base layer of Al, Cu, Mo or Ti or of alloys of said metals that have an almost black appearance due to a coating of substoichiometric zinc-molybdenum oxide with suitably selected layer thickness and thus show a high electrical conductivity.

The following properties can be achieved with such a layer system:

Tv<8%, preferably <4%

### Rv<15%

layer resistance <100Ω/square
simple wet etching, e.g. with diluted acids based on HNO₃, HCl, oxalic acid, acetic acid, phosphoric acid (also mixtures of said acids) or fluoride-containing compounds such as NH₄HF₂
small layer thickness <100 nm, preferably <60 nm.

The layer sequence is here: substrate/metal/black absorber layer. In an alternative embodiment of the layer system according to the invention, the layer sequence is inverse, namely: glass substrate/black absorber layer/metal.

Table 3 summarizes layer parameters and measurement results for a layer system of aluminum conductor paths with different thicknesses of the conductor paths d_{Al} and the absorber layers d_{Abs} of ZnO+31.4 wt. % Mo:

TABLE 3

| d_{Al} | d_{Abs} | Tv | Rv | R [symbol] |
|---|---|---|---|---|
| [nm] | [nm] | [%] | [%] | [Ω] |
| 10 | 40 | 10 | 9.5 | 13 |
| 15 | 35 | 5.2 | 20.1 | 7.7 |
| 20 | 30 | 2.6 | 35.1 | 4.1 |
| 10 | 45 | 8.9 | 6.1 | 13 |
| 15 | 45 | 4.2 | 6.3 | 4.1 |

Table 4 summarizes layer parameters and measurement results for a layer system of aluminum conductor paths with different thicknesses of the conductor paths d_{Al} and the absorber layers d_{Abs} of ZnO+37.9 wt. % Mo:

TABLE 4

| d_{Al} | d_{Abs} | Rv | Rv | R [symbol] |
|---|---|---|---|---|
| [nm] | [nm] | [%] | [%] | [Ω] |
| 10 | 40 | 7.3 | 11.6 | 12.5 |
| 15 | 35 | 4.2 | 11.6 | 7.5 |
| 20 | 30 | 2.3 | 19.7 | 12.5 |
| 10 | 45 | 6.1 | 13.3 | 12.5 |
| 15 | 45 | 3.0 | 10.7 | 4.0 |

The comparison with the layer system of Table 3 shows that the increased molybdenum oxide content of the absorber layers of Table 4 (37.9 wt. % in comparison with 31.4 wt. %) at the same layer thickness leads to a lower visual transmission of the layer system on the whole. The metallic conductor paths are still translucent at the small prevailing thicknesses, and measurement radiation can pass therethrough.

The optical layer properties are maintained in unchanged form also in the case of a rather long storage in air. Likewise, a thermal treatment at 150-220° C. in protective gas does not lead to any significant layer change.

In FIG. 8 the transmission T (in %) and the reflection R (in %) are plotted against the measurement wavelength λ (in nm) for the layer system d_{A1}=15 nm and d_{Abs}=45 nm (see last line of Table 4). The transmission T rises slightly with the wavelength and is below 5% over a whole wavelength range of 380 nm to 780 nm. The curve of reflection R shows a minimum at about 4% at a wavelength around 510 nm and is otherwise clearly below 20%.

The sputter target is produced as explained above with reference to the procedures 1 and 2. The absorber layers are produced in that the corresponding sputter target is sputtered off without addition of oxygen and is deposited as a layer on the conductor path.

Corresponding coatings were also produced on conductor paths consisting of other metals. The following ranges were obtained for the resistance of the layer system: R/square (Al)<15 ohm; R/square (Cu)<15 ohm;

### R/square (Mo)<100 ohm

It has been found that in the production of particularly thin conductor paths a comparatively high sputtering power (e.g. more than 5 W/cm²) is needed to obtain a high conductivity. This is particularly true for conductor paths of aluminum because with a small sputtering power (and thus with a small deposition rate) the metal atoms may too rapidly oxidize in the residual gas.

Moreover, it has been found that in layers produced from targets with molybdenum contents of more than 31 wt. % (calculated as the relation of the elemental content of molybdenum metal based on the total mass of the absorber layer, as explained above) the visual transmission is decreasing, but the visual reflection is increasing. The quality of the antireflection coating is decreasing. It is more difficult to provide thick metallic layers with non-reflecting surfaces than thin metal layers. However, metal layers that are too thin lead to low absorption. The minimum thickness which is here permitted depends on the wavelength-dependent absorption of the metal. Aluminum permits the thinnest metal layers, followed by copper.

The following Tables 5 and 6 summarize the data of thin metal layers of molybdenum (Table 5) and copper (Table 6) with the corresponding conductor path thickness d_{Mo} and d_{Cu}, respectively, for layer systems with absorber layers produced from a target of ZnO+Mo 37.9 wt. % and absorber layers, respectively, from a target of ZnO+Mo 31.4 wt. %, where the thickness of the respective absorber layers is designated with d_{Abs}.

TABLE 5

| | |
|---|---|
| ZnO—Mo37.9 wt. % | ZnO—Mo31.4 wt. % |

| d_{Mo} | C_{Abs} | Tᵥ | Rᵥ | Tᵥ | Rᵥ |
|---|---|---|---|---|---|
| [nm] | [nm] | [%] | [%] | [%] | [%] |
| 18 | 30 | 7.2 | 29 | 8.4 | 31.3 |
| 18 | 32 | 6.9 | 27 | 8.2 | 28.9 |
| 18 | 35 | 6.6 | 24.3 | 8 | 25.4 |
| 18 | 40 | 5.9 | 21 | 7.6 | 20 |
| 28 | 30 | 3.6 | 25.3 | 4.2 | 29.6 |
| 28 | 32 | 3.5 | 23.1 | 4.1 | 26.7 |
| 28 | 35 | 3.3 | 20.4 | 4 | 22.7 |
| 28 | 40 | 2.9 | 17.5 | 3.8 | 16.7 |
| 30 | 30 | 3.1 | 24.7 | 3.6 | 29.1 |
| 30 | 32 | 3 | 22.5 | 3.6 | 26.2 |
| 30 | 35 | 2.8 | 19.9 | 3.5 | 22.1 |
| 30 | 40 | 2.5 | 17.1 | 3.3 | 16.2 |
| 32 | 30 | 2.7 | 24.1 | 3.2 | 28.6 |
| 32 | 32 | 2.6 | 22 | 3.1 | 25.7 |
| 32 | 35 | 2.5 | 19.4 | 3 | 21.6 |
| 32 | 40 | 2.2 | 16.9 | 2.8 | 15.8 |
| 35 | 30 | 2.2 | 23.5 | 2.6 | 27.8 |
| 35 | 32 | 2.1 | 21.4 | 2.5 | 25 |
| 35 | 35 | 2 | 19 | 2.4 | 20.9 |
| 35 | 40 | 1.8 | 16.6 | 2.3 | 15.2 |

TABLE 6

| | |
|---|---|
| ZnO—Mo37.9 wt. % | ZnO—Mo31.4 wt. % |

| d_{Cu} | d_{Abs} | Tᵥ | Rᵥ | Tᵥ | Rᵥ |
|---|---|---|---|---|---|
| [nm] | [nm] | [%] | [%] | [%] | [%] |
| 40 | 30 | 6.7 | 10.3 | 9.1 | 9 |
| 40 | 32 | 6.2 | 10.9 | 8.7 | 7.5 |
| 40 | 35 | 5.6 | 12.4 | 8.1 | 5.9 |
| 40 | 40 | 4.7 | 15.8 | 7.1 | 5.1 |
| 45 | 30 | 5.1 | 9.6 | 6.9 | 9 |
| 45 | 32 | 4.7 | 10.3 | 6.6 | 7.3 |
| 45 | 35 | 4.2 | 11.8 | 6.2 | 5.6 |
| 45 | 40 | 3.5 | 15.4 | 5.4 | 4.7 |
| 50 | 30 | 3.8 | 9.2 | 5.2 | 9 |
| 50 | 32 | 3.6 | 9.8 | 5 | 7.2 |
| 50 | 35 | 3.2 | 11.4 | 4.6 | 5.4 |
| 50 | 40 | 2.7 | 15.1 | 4.1 | 4.4 |

### Adjustment of the Etch Rate of the Target Material

To be able to change the etch behavior of the layer material to a technically relevant extent, an additional component K3 was added to the target base material, wherein the relatively easily etchable oxidic component K1 (in the above embodiments; ZnO) was partly replaced by an added component K3 that was more difficult to etch. The influence thereof on the etch behavior was checked in several test series.

In these test series the respective fraction of the added component K3 was indicated in vol. %. The conversion to the previously used concentration data in wt. % was carried out on the basis of the specific densities of the individual components, such as e.g. Mo: 10.20 g/cm³; ZnO: 5.62 g/cm³; Nb₂O₅: 4.55 g/cm³. Table 7 shows the conversion result for various binary ZnO—Mo compositions of the base material.

TABLE 7

| Mo | Mo | ZnO | ZnO |
|---|---|---|---|
| vol. % | wt. % | vol. % | wt. % |
| 5 | 8.78 | 95 | 91.22 |
| 20 | 31.38 | 80 | 68.62 |
| 25 | 37.88 | 75 | 62.12 |

In a first test series, the oxide Nb₂O₅ which is rather difficult to etch in comparison with ZnO was stepwise admixed as the added component K3 to the base material ZnO+25 vol. % Mo. ZnO was replaced by up to a content of 50 vol. % Nb₂O₅ in the target (and the absorber layer produced therefrom).

In a further test series, TiO₂ was used as the added component K3 instead of Nb₂O₅.

Thus, the target materials produced in this way and the layer produced therefrom always contained 25 vol. % metallic Mo and 75 vol. % of oxides of the components K1 and K3; for the improvement of the electrical conductivity of the sputter target the oxides of the added component Nb₂O₅ and TiO₂, respectively, were present in a slightly substoichiometric form (about 1-10% oxygen deficit based on the stoichiometric oxygen content).

The compositions of the respective target materials, the target designations (column: “sample”), and the specific ensuing densities and the data on the specific resistances ρ (in mΩcm) are specified in Tables 8 and 9.

TABLE 8

| | | | | | | | den- | | kappa |
|---|---|---|---|---|---|---|---|---|---|
| | Mo | Mo | ZnO | ZnO | Nb₂O₃ | Nb₂O₃ | sity | | @ |
| Sam- | vol. | wt. | vol. | wt. | vol. | wt. | g/ | ρ | 550 |
| ple | % | % | % | % | % | % | cm³ | mΩcm | nm |
| X1 | 25 | 38.18 | 70 | 58.44 | 5 | 3.38 | 6.732 | 37 | 0.75 |
| X2 | 25 | 38.48 | 65 | 54.70 | 10 | 6.81 | 6.678 | | 0.81 |
| X3 | 25 | 38.80 | 60 | 50.90 | 15 | 10.30 | 6.625 | | 0.86 |
| X4 | 25 | 39.11 | 55 | 47.04 | 20 | 13.85 | 6.571 | 33 | 0.90 |
| X5 | 25 | 39.76 | 45 | 39.12 | 30 | 21.12 | 6.464 | 31 | 0.99 |
| X6 | 25 | 40.43 | 35 | 30.94 | 40 | 28.63 | 6.357 | 14 | 1.08 |
| X7 | 25 | 41.12 | 25 | 22.48 | 50 | 36.40 | 6.250 | 7.4 | 1.18 |

TABLE 9

| | Mo | Mo | ZnO | ZnO | TiO₂ | TiO₂ | | | kappa |
|---|---|---|---|---|---|---|---|---|---|
| Sam- | vol. | wt. | vol. | wt. | vol. | wt. | density | ρ | @550 |
| ple | % | % | % | % | % | % | g/cm³ | mΩcm | nm |
| X8 | 25 | 40.42 | 45 | 39.77 | 30 | 19.81 | 6.359 | 18 | 1.05 |

Of the targets according to Tables 8 and 9, absorber layers of layer systems (double layers) were respectively produced by DC sputtering in argon without addition of oxygen. The absorption coefficient kappa (measured at a wavelength of 550 nm) of the absorber layers produced in this way is indicated in Tables 8 and 9. Thus, similarly good values as in the layer structures named in Table 1 are achieved.

By analogy, the absorber layer was sputtered onto a thin metal layer based on Al, Mo, Ti, Cu, as has been explained above. The thicknesses of the individual layers of the layer systems produced thereby correspond to those of Tables 3 to 6.

The target materials according to Tables 8 and 9 were also used for producing black layer stacks in that a thin antireflection layer is first deposited on a glass substrate and an absorber layer is produced thereon, as has been explained above. The respective antireflection layers can be produced from the materials which are generally known for this purpose. Preferably, antireflection layer and absorber layer are however produced by sputtering one and the same target material, as has already been described above; here, during deposition of the absorber layer the sputter atmosphere has no or only a slight content of reactive gas and the antireflection layer is sputtered with addition of oxygen, so that it becomes almost dielectric and still has an oxygen deficiency of about 4%. The thicknesses of the individual layers of the layer systems produced in this way correspond to those of Table 2.

The etch rates were measured on sputter layers from the target material. To this end absorber layers (individual layer) with a respective thickness of 100 nm were sputtered without reactive gas from the respective targets. The layers were etched in an etching solution at 20° C. for such a long time until they were optically transparent and without residues. The time up to the complete disappearance of the sputter layer was noted down as etching period. The etching solution has the following composition:

### 785 ml H₂O

### 215 ml H₂O₂

### 30 g K₂S₂O₅

### 15 g H₅F₂N(═NH₄HF₂)

For each of the target materials named the measurement was repeated 10 times. The mean value of the etching period t (in s) obtained therefrom and the specific etch rates v (in nm/s) resulting therefrom are indicated in Table 10. Sample X0 (corresponds to Sample 2 of Table 1) serves as a reference value, representing the target base material without additional added component K3.

TABLE 10

| | Mo | ZnO | K3 | t | v |
|---|---|---|---|---|---|
| Sample | vol. % | vol. % | vol. % | [s] | nm/s |
| X0 | 25 | 75 | 0 | 98 | 1.53 |
| X1 | 25 | 70 | 5 | 114 | 1.31 |
| X4 | 25 | 55 | 20 | 240 | 0.63 |
| X5 | 25 | 45 | 30 | 321 | 0.48 |
| X6 | 25 | 35 | 40 | 354 | 0.42 |
| X7 | 25 | 25 | 50 | 422 | 0.36 |
| X8 | 25 | 45 | 30 | 194 | 0.77 |

In Samples X1 to X7 the added component K3 is Nb₂O₃ (from Table 8); in Sample X8, the added component K3 is TiO₂ (from Table 9). The comparison of Samples X0 to X7 shows that with the same type of the added component K3 the etch rate of the absorber layer is decreasing with an increasing content of added component. Amount of added component K3 and etch rate are here scaled, as shown in the diagram of FIG. 10. The etch period t (in s) is here plotted against the volume proportion C of the added component K3.

Due to the linear dependence of etch rate and composition, the specific etch rate can also be determined for higher contents of added component K3 and for other compositions of the target material with added components K3 other than the above-mentioned ones in a simple manner and with adequate accuracy. The etch rate of the layer material can thereby easily be adapted to the respective application-specific requirement.

Samples X2 to X7 were additionally subjected to a so-called “Pressure Cooker Test” according to DIN EN 60749-33. The samples are here treated in an autoclave for one hour: hot pressure storage in 100% relative humidity/121±2 C.°/202 kPa. Thereafter only a minor—acceptable—decrease in transmission of about 1% was observed.

FIG. 11 shows the curve of the reflection R (in %) over the wavelength range λ (in nm) of von 350 nm to 750 nm. The reflection was here measured on the substrate side (glass); the indicated reflection values contained about 4% of the reflection of the glass substrate.

The continuous curve A represents the following layer system:
Glass substrate
absorber layer: ZnO—Mo 25 vol. %—Nb₂O₃ 20 vol. %; thickness 40 nm
metal layer: Mo; thickness: 50 nm.

The visual transmission of this layer system is 0.7%. The thin absorber layer was deposited by sputtering the sputter target without addition of oxygen (no reactive gas in the sputter atmosphere).

Curve B marked by broken line represents the following layer system:
Glass substrate
Antireflection layer: ZnO—Mo 25 vol. %—Nb₂O₃ 5 vol. %; thickness: 60 nm
absorber layer: ZnO—Mo 25 vol. %—Nb₂O₃ 20 vol. %; thickness: 250 nm

The visual transmission of this layer system is 2.7%. The thin antireflection layer was here deposited by sputtering the sputter target in a sputter atmosphere with 23% oxygen (more exactly: 60 sccm oxygen+200 sccm argon).

Apart from the added component K3 niobium oxide and titanium oxide as outlined with reference to the above embodiments, hafnium oxide, tantalum oxide, vanadium oxide and aluminum oxide also reduce the etch rate of the target base material.

### Example 5

### Single-Layered Black Absorber Layer

A single-layered absorber layer S2 (without antireflection layer S1) deposited on a glass substrate, with the chemical composition of Sample 1 of Table 1, turns out to be visually opaque and black. FIGS. 12 and 13 show the curve of the reflection R (in %) and the transmission T (in %) over the wavelength range λ (in nm) of 350 nm to 750 nm. The dark gray curve L1 must here be assigned to a thin single-layered absorber layer with a mean layer thickness of 125 nm, and the light gray curve L2 to a single-layered absorber layer with a mean thickness of 145 nm.

The visual reflection of the thinner absorber layer L1 is 8.9% and that of the thicker absorber layer L2 is 10%. The reflection measured on the bottom side of the glass substrate remains below 12% over the whole wavelength range. In the range of the wavelengths that correspond to the maximum eye sensitivity in daylight (around 550 nm), the reflections values are even around 10% or below, resulting—in this wavelength range after deduction of the reflection value of 4% (reflection on the not antireflection-coated glass plate front side)—in a reflection of about 6% to be really ascribed to the absorber layer.

The transmission T rises over the wavelength range with the wavelength from values of about 3% and reaches values of about 18% at 740 nm (curve L2; thicker layer) or about 22% (curve L1, thinner layer), which thus appears to be visually largely opaque.

1-24. (canceled)

25. A light-absorbing layer having, at a wavelength of 550 nm, an absorption index kappa of more than 0.7, the light-absorbing layer being made from a layer material comprising:
an oxidic matrix based on a base component K1 selected from the group consisting of zinc oxide, tin oxide and indium oxide, and on an added component K3 which replaces the base component K1 up to a fraction y between 0 and 75% by weight, the added component K3 being selected from the group consisting of niobium oxide, hafnium oxide, titanium oxide, tantalum oxide, vanadium oxide, yttrium oxide, zirconium oxide, aluminum oxide and mixtures thereof; and
a blackening component K2 selected from the group consisting of molybdenum, tungsten and alloys and mixtures thereof, the blackening component K2 being distributed in the oxidic matrix and being present either as (i) a metal or (ii) a substoichiometric-oxidic or a substoichiometric-oxynitride compound of the metal, such that the layer material has a degree of reduction which is defined by an oxygen content of not more than 65% of a stoichiometrically maximum oxygen content, a fraction x of the blackening component K2 being calculated from a weight of its elemental fraction based on a weight of the layer material and being in the range between 20 and 50% by weight.

26. The light-absorbing layer according to claim 25, wherein the fraction x of the blackening component is >25 wt. %.

27. The light-absorbing layer according to claim 25, wherein the layer material has a predetermined specific target etch rate and the fraction y of the added component K2 in wt. % is set in response to the target etch rate, and wherein the fraction y of the added component K2 in wt. % is one of:
0<Y<15;
15<Y<30;
30<Y<45;
45<Y<60; and
Y<100/3

28. The light-absorbing layer according to claim 25, wherein the layer material has an optically homogeneous and amorphous structure, such that it is without crystalline structures that are detectable by way of X-ray diffractometer measurements.

29. The light-absorbing layer according to claim 25, wherein the blackening component K2 is present as a substoichiometric-oxidic or substoichiometric-oxnyitride oxygen compound of the metal or as a metal, and wherein the layer material has a degree of reduction which is defined by an oxygen content between 30% and 65% of the stoichiometrically maximally possible oxygen content.

30. A light-absorbing layer system comprising:
the light-absorbing layer according to claim 25 as an absorber layer facing away from a viewer, and
an antireflection layer facing the viewer,
wherein, in the wavelength range of 380 nm to 780 nm, the light-absorbing layer system has a visual transmission Tv of less than 2% and a visual reflection Rv of less than 6%.

31. The light-absorbing layer system according to claim 30, wherein the visual transmission Tv is less than 1% and the visual reflection Rv is less than 3%.

32. The light-absorbing layer system according to claim 30, wherein the light-absorbing layer has a layer thickness of less than 600 nm, and wherein a layer thickness of the antireflection layer is in the range of 45 nm to 60 nm.

33. A light-absorbing layer system comprising:
the light-absorbing layer according to claim 25 as an absorber layer facing a viewer, and
a metallic layer which faces away from the viewer and serves as a conductor path.

34. The light-absorbing layer system according to claim 33, wherein the metallic layer contains one or more of metals selected from the group consisting of Al, Mo, Cu, and Ti.

35. The light-absorbing layer system according to claim 33, wherein, in the wavelength range of 380 nm to 780 nm, the light-absorbing layer system has a visual transmission Tv of less than 8% and a visual reflection Rv of less than 15%.

36. The light-absorbing layer system according to claim 35, wherein the light-absorbing layer system has a total thickness of less than 90 nm.

37. The light-absorbing layer system according to claim 33, wherein the light-absorbing layer system has a layer resistance of less than 100 ohm/square.

38. The light-absorbing layer system according to claim 33, wherein the metallic layer consists of aluminum or of an aluminum base alloy and has a thickness in the range of 17 nm to 21 nm, and wherein a thickness of the absorber layer is in the range of 30 nm to 50 nm.

39. The light-absorbing layer system according to claim 33, wherein the metallic layer consists of molybdenum or of an molybdenum base alloy and has a thickness in the range of 15 nm to 50 nm, and wherein a thickness of the absorber layer is in the range of 35 nm to 50 nm.

40. The light-absorbing layer system according to claim 33, wherein the metallic layer consists of copper or a copper base alloy and has a thickness in the range of 40 nm to 50 nm, and wherein a thickness of the absorber layer is in the range of 28 nm to 50 nm.

41. A sputter target for producing a light-absorbing layer according to claim 25, the sputter target consisting of a target material comprising:
an oxidic matrix based on a base component K1 selected from the group consisting of zinc oxide, tin oxide and indium oxide, and on an added component K3 which replaces the base component K1 at a fraction y between 0 and 75 wt. %, the added component being selected from the group consisting of niobium oxide, hafnium oxide, titanium oxide, tantalum oxide, vanadium oxide, yttrium oxide, zirconium oxide, aluminum oxide and mixtures thereof, and
a blackening component K1 distributed in the matrix, the blackening component K1 being selected from the group consisting of molybdenum, tungsten and alloys and mixtures thereof, the blacking component K2 being present as (i) a metal and/or (ii) a substoichiometric-oxidic or substoichiometric-oxynitride compound of the metal, such that the target material has a degree of reduction which is defined by an oxygen content of not more than 65% of a stoichiometrically maximal oxygen content, a fraction x of the blackening component K2 being calculated from a weight of its metal fraction based on a weight of the target material and being in the range between 20 and 50 wt. %.

42. The sputter target according to claim 41, wherein the fraction x of the blackening component K2 is at least 25 wt. %.

43. The sputter target according to claim 42, wherein the blackening component K2 is present in metallic form.

44. The sputter target according to claim 41, wherein the fraction y of the added component K3, in response to a target etch rate of a layer to be produced from the sputter target, is one of the following: between 0 and 15 wt. %, between 15 and 30 wt. %, between 30 and 45 wt. %, and between 45 and 60 wt. %.

45. The sputter target according to claim 44, wherein the added component K3 is present as an oxide.

46. The sputter target according to claim 41, wherein the target material has a density of more than 95% of the theoretical density, a content of impurities of less than 500 wt. ppm, and a degree of reduction which is defined by an oxygen content of between 30 and 65% of the stoichiometrically maximally possible oxygen content.

47. A method for producing the light-absorbing layer system according to claim 30, the method comprising:
depositing a light-absorbing layer by DC or MF sputtering of a sputter target in a sputter atmosphere containing a noble gas and a reactive gas in the form of oxygen and/or nitrogen,
wherein a content of the reactive gas in the sputter atmosphere is set to not more than 10 vol. %.

48. The method according to claim 47, wherein for deposition of an antireflection layer and for deposition of an absorber layer, a sputter target is used with nominally the same composition, and wherein the sputter atmosphere during the deposition of the antireflection layer has a higher content of the reactive gas than during the deposition of the absorber layer, resulting in an oxygen deficit in the antireflection layer that is less than 5%.

49. A method for producing the light-absorbing layer system according to claim 33, the method comprising:
depositing a light-absorbing layer by DC or MF sputtering of a sputter target in a sputter atmosphere containing a noble gas and a reactive gas in the form of oxygen and/or nitrogen, wherein a content of the reactive gas in the sputter atmosphere is set to not more than 10 vol. %.
